(19) United States
(12) Patent Application Publication
(10) Pub. No.: US 2005/0151469 A1
(43) Pub. Date: Jul. 14, 2005

(54) Light emitting element and process for producing the same

(75) Inventor: Tomoyuki Tachikawa, Tokyo-To (JP)

Correspondence Address: BURR & BROWN, PO BOX 7068, SYRACUSE, NY, 13261-7068, US

(73) Assignee: Dai Nippon Printing Co., Ltd., Shinjuku-Ku (JP)

(21) Appl. No.: 11/025,354

(22) Filed: Dec. 29, 2004

(30) Foreign Application Priority Data
Jan. 9, 2004 (JP) 2004-3999

(51) Int. Cl. H01J 1/62

(52) U.S. Cl. 313/506

(57) ABSTRACT

There is provided a light emitting element comprising a luminescent layer provided without any partition wall for partitioning luminescent layers. The light emitting element comprises a substrate and a first electrode, a plurality of luminescent layers, and a second electrode provided on the substrate in that order. The plurality of luminescent layers are provided without providing any partition wall between adjacent luminescent layers.

### TECHNICAL FIELD

The present invention relates to a light emitting element and a process for producing the same.

### BACKGROUND ART

Light emitting elements, particularly electroluminescent elements (hereinafter often referred to as “EL element”) which are field-effect light emitting elements, can realize high-intensity luminescence at a low applied voltage and further have high durability and high service life and thus are utilized in displays and the like.

In the production of a light emitting element, a luminescent layer should be formed by patterning of one or a plurality of luminescent materials. A vacuum deposition method or an ink jet printing method has been proposed as a method for luminescent layer pattern formation using a luminescent material. For example, an ink jet printing method has been proposed in which a coating liquid (ink) containing a luminescent material and a solvent is ejected to form a luminescent layer pattern (Japanese Patent Laid-Open No. 323276/2000).

In forming a luminescent layer pattern by an ink jet printing method, partition walls should be provided for holding a coating liquid (ink) in desired places. The partition walls should have a height of about 5 μm to 10 μm. The partition walls function to hold the ink in desired places and to prevent the entry of other luminescent material to clearly define individual patterned luminescent layers.

The presence of the partition walls, however, forms a concave-convex shape in the light emitting element and, as a result, often poses a problem that, when an electrode and a protective layer are formed on the luminescent layer, troubles such as disconnection occur, often resulting in a lowered yield.

Accordingly, it is of urgent necessity to develop a light emitting element free from or reduced concaves and convexes on its surface and a production process thereof.

### SUMMARY OF THE INVENTION

The present inventors have now found that patterning of a luminescent layer without providing partition walls for partition into individual luminescent layers can provide a light emitting element which is free from concaves and convexes, can effectively prevent breaking of the electrode, and has an even plane. The present invention has been made based on such finding. Accordingly, an object of the present invention is to provide a light emitting element, in which the formation of concaves and convexes in the light emitting element has been suppressed and which has enhanced evenness in the luminescent layer and has prevented breaking of the electrode, and a process for producing the same.

Thus, according to the present invention, there is provided a light emitting element comprising:
a substrate; and at least a first electrode, luminescent layers, and a second electrode provided on said substrate in that order,
said plurality of luminescent layers being provided without providing any partition wall between adjacent luminescent layers.

Further, according to the present invention, there is provided a process for producing a light emitting element comprising
a substrate; and at least a first electrode, luminescent layers, and a second electrode provided on said substrate in that order,
said plurality of luminescent layers being provided without providing any partition wall between adjacent luminescent layers,
said process comprising the step of forming a plurality of luminescent layer patterns by photolithography or printing (except for ink jet printing) without providing any partition wall between adjacent luminescent layers.

### BRIEF DESCRIPTION OF THE DRAWINGS

FIG. 1 is a cross-sectional view of the light emitting element according to the present invention;

FIG. 2 is a cross-sectional view of the light emitting element according to the present invention;

FIG. 3 is a cross-sectional view of the light emitting element according to the present invention; and

FIG. 4 is a cross-sectional view of a light emitting element formed by a conventional ink jet printing method.

### DESCRIPTION OF REFERENCE CHARACTERS IN THE DRAWINGS

1: substrate, 2: first electrode, 3: luminescent layer, 4: second electrode, 5: insulating layer, 10: partition wall, and 11: indication of disconnection.

### DETAILED DESCRIPTION OF THE INVENTION

### Light Emitting Element and Production Process Thereof

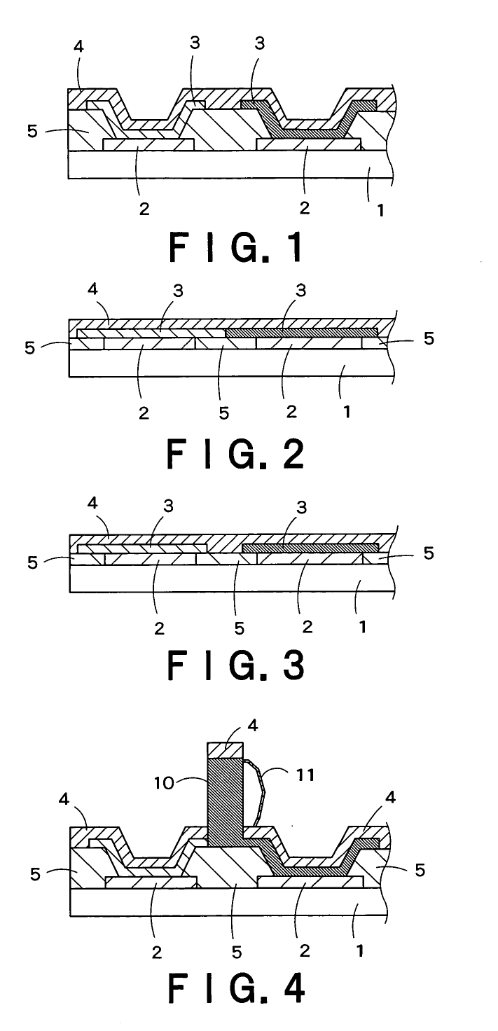

The light emitting element according to the present invention will be explained with reference to FIGS. 1 to 3. FIG. 1 is a cross-sectional view of the light emitting element according to the present invention. In FIG. 1, a first electrode 2 is provided on a substrate 1. A luminescent layer 3 is provided on the surface of the first electrode 2. In this light emitting element, no partition wall is provided between adjacent luminescent layers. Therefore, when the surface is coated after luminescent layer formation, a light emitting element can be formed without forming concaves and convexes on the whole light emitting element. In particular, in FIGS. 2 and 3 (cross-sectional views) showing another embodiment of the light emitting element according to the present invention, adjacent luminescent layers are joined to each other (FIG. 2) or are formed while providing given spacing therebetween (FIG. 3). It is understood that the whole form of the light emitting element is free from concaves and convexes and substantially plane. FIG. 4 is a cross-sectional view of a conventional light emitting element in which a partition wall 10 is provided in forming luminescent layers. As can be seen from FIG. 4, the partition wall 10 provided in the formation of the luminescent layer 3 stays, and, as a result, the light emitting element per se has large concaves and convexes. Further, the presence of the partition wall often causes disconnection between the luminescent layer 3 and the second electrode (numeral 11 in the drawing).

According to the production process of the present invention, a luminescent layer pattern is formed by photolithography or printing (except for printing by ink jet recording). In this case, a plurality of luminescent layers are formed without providing any partition wall between adjacent luminescent layers. According to the production process of the present invention, there is no need to provide partition walls indispensable for vapor deposition and ink jet printing. Therefore, mass production of a light emitting element, which can simplify the production process, has reduced concaves and convexes and has prevented disconnection, can be realized.

Photolithography is a conventional method. This method will be briefly described. In this method, a series of treatments are carried out. A coating liquid containing a luminescent material for luminescent layer formation is coated onto a substrate. The coating is optionally prebaked. The coating formed area is treated by exposure (laser direct drawing) through light irradiation or the like, subjected to development and optionally post-baking, and then subjected to optional treatment such as etching, sandblasting, and baking.

The printing method (except for the ink jet printing method) refers to all the methods in which, in patterning the luminescent layer, a coating liquid comprising a luminescent material is printed so as to conform to a desired pattern. In the present invention, any printing method except for printing by ink jet recording in which the coating liquid is ejected to form an image may be used. Preferably, various printing methods such as gravure printing, offset printing, screen printing, stamp printing, laser transfer printing, or thermal transfer printing may be utilized. These printing methods may be any conventional method.

The printing method (except for the ink jet printing method) refers to all the methods in which, in patterning the luminescent layer, a coating liquid comprising a luminescent material is printed so as to conform to a desired pattern. The printing method is used only in patterning of the luminescent layer (buffer layer). In this case, treatments such as development, exposure, and etching may be carried out in the same manner as those described above in connection with the photolithography.

In one embodiment of the production process according to the present invention, a plurality of luminescent layers may be formed by forming a first electrode on a substrate, then coating a coating liquid containing a luminescent material, coating a photoresist liquid, prebaking the coating, then subjecting the coating to exposure (positive or negative), subjecting the exposed coating to development with a resist developing solution, and then conducting etching. These treatments may be repeated a plurality of times to stack a plurality of luminescent layers on top of each other.

Substrate

The substrate is used as a lower surface of the first electrode and as such is preferably transparent. Specific examples of substrates include substrates of quartz, glass, silicon wafers, and glass with TFT (thin-film transistor) formed thereon, or polymeric substrates of polycarbonate (PC), polyethylene terephthalate (PET), polybutylene terephthalate (PBT), polyphenylene sulfide (PPS), polyimide (PI), polyamideimide (PAI), polyether sulfone (PES), polyether imide (PEI), polyetherether ketone (PEEK) and the like. Among them, quartz, glass, silicon wafers, or polymeric substrates of polyimide (PI), polyamide-imide (PAI), polyether sulfone (PES), polyether imide (PEI), polyetherether ketone (PEEK) and the like are particularly preferred. The thickness of the substrate is about 0.1 to 2.0 mm.

First Electrode

The material for the first electrode may be a metallic material, an organic material, an inorganic material, or a composite material thereof. Among them, a metallic material is preferred. Specific examples of metallic materials include chromium, nickel, tungsten, manganese, indium, tin, zinc, aluminium, gold, silver, tantalum, platinum, palladium, molybdenum, niobium, a combination of two or more of the above metals, alloys composed mainly of these metals, or a combination of the above metallic materials. The metallic material is preferably selected from the group consisting of chromium, nickel, tungsten, manganese, indium, tin, and zinc.

In a preferred embodiment of the present invention, the metal layer comprises a laminate of one or more alloys and one or more metals or alloys. The alloy particularly preferably has excellent heat resistance and corrosion resistance, and examples of such alloys include Cr-base alloys (for example, Cr—Al—Mn—Si alloy and Cr—Mn—C—Si alloy) and Ni—Cr-base alloys (for example, Cr—Ni—C—Mn alloy, Cr—Ni—Mn—Si alloy, Cr—Ni—Mo—Mn alloy, Cr—Ni—Ti—Mn alloy, Cr—Ni—Ta—Mn alloy, and Cr—Ni—Cu—C alloy). Alloys comprising nickel, titanium, tantalum, and zirconium include Ti-base alloys (for example, Ti—Al—Sn alloy, Ti—Mn alloy, and Ti—Al—V alloy), and Zr—Ni-base alloys (for example, Zr—Sn—Fe alloy, Zr—Sn—Fe—Cr alloy, Ni—Cr—Fe—Ti alloy, Ni—Cr—Mo—Fe alloy, Ni—Cu—Fe alloy, Ni—Cr—Fe alloy, and Ni—Mn—Al—Si alloy). Further, amorphous metal alloys may also be preferably used. Specific examples of amorphous metal alloys include metal-semi-metal (metal: e.g., Fe (iron), Co (cobalt), Ni (nickel), Nb (niobium), semimetal: e.g., P (phosphorus), B (boron), Si (silicon)) amorphous alloys and metal-metal (e.g., Fe—Zr, La—Cu, U—Co, and Ca—Al) amorphous alloys.

Methods for forming the metal layer as the first electrode on the substrate include sputtering, vacuum heat deposition, EB deposition, and ion plating.

Luminescent Layer

The luminescent material for luminescent layer formation may be any inorganic luminescent material or organic luminescent material. In the present invention, if necessary, a dopant may be added. The dopant is added to the luminescent layer, for example, for improving luminescence efficiency or changing luminescence wavelength.

1) Inorganic Luminescent Material

Specific examples of colorant materials include zinc sulfide type phosphors (for example, ZnS:Mn, ZnS:Tb, Zn—Mg—S:Mn), strontium sulfide type phosphors (for example, SrS:Ce), calcium sulfide type phosphors (for example, CaS:Eu), and barium sulfide type phosphors (for example, Ba—Al—S:Eu). Metal indicated after “: (colon)” in the exemplified inorganic luminescent material refers to a dopant.

2) Organic Luminescent Material

Organic luminescent materials include organic compounds (low-molecular compound or high-molecular compound) which emit fluorescence or phosphorescence. Specific examples of organic luminescent materials are as follows.

1. Colorant Material

Specific examples of colorant materials include cyclopentamine derivatives, tetraphenylbutadiene derivatives, triphenylamine derivatives, oxadiazole derivatives, pyrazoloquinoline derivatives, distyrylbenzene derivatives, distyrylarylene derivatives, pyrrole derivatives, thiophene ring compounds, pyridine ring compounds, perinone derivatives, perylene derivatives, oligothiophene derivatives, trifumanylamine derivatives, oxadiazole dimers, and pyrazoline dimers.

2. Metal Complex Material

Specific examples of metal complex materials include quinolinol aluminum complex, benzoquinolinol beryllium complex, benzoxazolyl zinc complex, benzothiazole zinc complex, azomethyl zinc complex, porphyrin zinc complex, europium complex, and metal complexes in which the center metal is aluminum (Al), zinc (Zn), beryllium (Be) or the like, or a rare earth metal such as terbium (Tb), eruopium (Eu), or dysprosium (Dy) while the ligand is oxadiazole, thiadiazole, phenylpyridine, phenylbenzoimidazole, quinoline or other structures.

3. Polymeric Materials

Specific examples of polymeric materials include poly-p-phenylenevinylene derivatives, polythiophene derivatives, poly-p-phenylene derivatives, polysilane derivatives, polyacetylene derivatives, polyfluorene derivatives, polyvinylcarbazole derivatives, and polymers prepared by polymerizing the above colorants or metal complex materials.

In the present invention, specific examples of blue emitting materials among the above luminescent materials include distyrylarylene derivatives, oxadiazole derivatives and polymers thereof, polyvinylcarbazole derivatives, poly-p-phenylene derivatives, and polyfluorene derivatives, preferably polyvinylcarbazole derivatives, poly-p-phenylene derivatives, and polyfluorene derivatives. Specific examples of green emitting materials include quinacridone derivatives, coumarin derivatives, and polymers thereof, poly-p-phenylenevinylene derivatives and polyfluorene derivatives, preferably poly-p-phenylenevinylene derivatives and polyfluorene derivatives. Specific examples of red emitting materials include coumarin derivatives, thiophene ring compounds, and polymers thereof, poly-p-phenylenevinylene derivatives, polythiophene derivatives, and polyfluorene derivatives, preferably poly-p-phenylenevinylene derivatives, polythiophene derivatives, and polyfluorene derivatives.

3) Dopant

Dopants may be added to the luminescent layer, e.g., for improving luminescence efficiency or changing luminescence wavelength. Such dopants may be the same as those described above in connection with the inorganic luminescent material. Organic luminescent materials include, for example, perylene derivatives, coumarin derivatives, rubrene derivatives, quinacridone derivatives, squalium derivatives, porphyrin derivatives, styryl dyes, tetracene derivatives, pyrazolone derivatives, decacyclene, and phenoxazone.

The thickness of the luminescent layer may be 2 to 200 nm. In a preferred embodiment of the present invention, when a plurality of luminescent layers are stacked on top of each other, the difference in level between luminescent layers is not less than 0 μm and not more than 3 μm. The upper limit of the difference in level between luminescent layers is preferably 1 μm, more preferably 0.5 μm.

In another preferred embodiment of the present invention, the thickness of one luminescent layer in the plurality of luminescent layers is not less than 0 μm and not more than 3 μm. Preferably, the lower limit of the thickness is 0.001 μm, and the upper limit of the thickness is 0.5 μm. More preferably, the upper limit of the thickness is 0.1 μm.

Second Electrode

The second electrode may be as described in connection with the first electrode layer. When any one of the first and second electrodes is a positive electrode, the other electrode is a negative electrode.

Optional Layer

The light emitting element according to the present invention basically comprises a substrate, a first electrode, a luminescent layer, and a second electrode. The light emitting element may further comprise the following optional layers.

1) Buffer Layer

The light emitting element according to the present invention may comprise a buffer layer, preferably between the first electrode and the luminescent layer or between the luminescent layer and the second electrode. In the present invention, the buffer layer is a layer which is formed so as to facilitate charge injection into the luminescent layer. This layer contains an organic material, particularly an organic conductor or the like. For example, the buffer layer may be formed of an electrically conductive polymer which can enhance the efficiency of hole injection into the luminescent layer and can flatten concaves and convexes on the surface of the electrode or the like.

Specific examples of materials for forming the buffer layer include polymers of hole transport materials such as polyalkylthiophene derivatives, polyaniline derivatives, and triphenyl amine, sol-gel films of inorganic compounds, films of polymers of organic materials such as trifluoromethane, and organic compound films containing Lewis acid.

Methods usable for buffer layer formation include a method using vapor deposition or other electrodeposition of the material for forming the buffer layer, or a coating method using a melt, solution or mixed liquid of the material, such as spin coating, casting, dipping, bar coating, blade coating, roll coating, gravure coating, flexo printing, or spray coating. When the buffer layer has high electrical conductivity, preferably, patterning is carried out so that crosstalk is prevented while maintaining diode characteristics of the element. The thickness of the buffer layer is usually about 10 to 200 nm.

2) Insulating Layer

The luminescent element according to the present invention may comprise an insulating layer, preferably provided on an edge part of the first electrode patterned on the substrate and on a nonluminescent part of the luminescent element. In the formation of the insulating layer, the insulating layer may previously be provided so that the luminescent part is in an opening form. The formation of the insulating layer can suppress the formation of defects, e.g., by shortcircuiting of the light emitting element and can provide a light emitting element which has long service life and can stably emit light.

The insulating layer may be patterned using, for example, an ultraviolet-curable resin or the like in a thickness of about 1 μm. In the present invention, when the luminescent layer or the like is patterned by dry etching, preferably, the insulating layer has resistance to dry etching. When the resistance to dry etching is low, preferably, the insulating layer is formed in a thickness of not less than 1 μm, preferably approximately not less than 1.5 μm and not more than 10 μm, to prevent the occurrence of defects caused by dry etching.

Etching in Production of Light Emitting Element

In the present invention, etching of the luminescent layer and the buffer layer may be carried out by either a wet process or dry etching (dry process). Dry etching characterized by anisotropic properties is preferred. Reactive ion etching is preferred as the dry etching process. When the reactive ion etching is used, the organic material undergoes a chemical reaction to form a compound with reduced molecular weight and consequently can be volatilized or vaporized and removed from the top of the substrate. As a result, etching accuracy is high, and fabrication in a short time can be realized.

In dry etching, the use of oxygen per se or oxygen-containing gas is preferred. When oxygen per se or oxygen-containing gas is used, the organic luminescent layer can be removed through decomposition by an oxidation reaction of the organic luminescent layer and unnecessary organic materials can be removed from the top of the substrate. Therefore, high etching accuracy and fabrication in a short time can be realized. Further, under this condition, an oxide transparent conductive film such as ITO commonly used in the art is not etched. Therefore, advantageously, the surface of the electrode can be cleaned without sacrificing electrode characteristics.

In dry etching, atmospheric plasma is preferably used. When atmospheric plasma is used, dry etching, which usually requires a vacuum device, can be carried out under atmospheric pressure. This can shorten the treatment time and can reduce the cost. In this case, etching can utilize oxidative decomposition of the organic material with oxygen, in the air, converted to plasma. Alternatively, the gas composition of the reaction atmosphere can be regulated to a desired one by gas replacement and circulation before the regulated gas is used.

### EXAMPLE 1

Preparation of Light Emitting Element

1) Formation of First Buffer Layer

A 6-inch patterned ITO substrate with a sheet thickness of 1.1 mm was cleaned and used as a base body and a first electrode. A coating liquid (Bayer; Baytron P) (0.5 ml) for a buffer layer was dropped on a center part of the substrate for spin coating (while holding at 2500 rpm for 20 sec) to form a buffer layer. The buffer layer had a thickness of 80 nm.

2) Formation of First Luminescent Layer

A coating liquid (70 parts by weight of polyvinylcarbazole, 30 parts by weight of oxadiazole, 1 part by weight of dicyanomethylene pyran derivative, and 4900 parts by weight of monochlorobenzene) which is a red luminescent organic material (1 ml) was placed on the buffer layer and was dropped on a center part of the substrate for spin coating (while holding at 2000 rpm for 10 sec) to form a first luminescent layer. The first luminescent layer had a thickness of 80 nm.

A positive-working photoresist liquid (manufactured by Tokyo Ohka Kogyo Co., Ltd.; OFPR-800) (2 ml) was dropped on a center part of the base body for spin coating (while holding at 500 rpm for 10 sec and then holding at 2000 rpm for 20 sec) to form a coating. The coating had a thickness of about 1 μm.

Prebaking was carried out at 80° C. for 30 min. Thereafter, the assembly, together with an exposure mask, was set in an alignment exposure machine, and ultraviolet light was applied to a luminescent layer part to be removed except for the first luminescent layer. Development was carried out with a resist developing solution (manufactured by Tokyo Ohka Kogyo Co., Ltd.; NMD-3) for 20 sec, followed by washing with water to remove the photoresist layer in its exposed areas. Post-baking was carried out at 120° C. for 30 min. The buffer layer and the luminescent layer in its parts from which the photoresist layer had been removed was then removed by reactive ion etching using oxygen plasma. The photoresist was removed with acetone. Thereafter, 2 ml of a positive-working photoresist liquid (manufactured by Tokyo Ohka Kogyo Co., Ltd.; OFPR-800) was again dropped on a center part of the base body for spin coating (while holding at 500 rpm for 10 sec and then holding at 2000 rpm for 20 sec) to form a coating. The coating had a thickness of about 1 μm.

Prebaking was carried out at 80° C. for 30 min. Thereafter, the assembly, together with an exposure mask, was set in an alignment exposure machine, and ultraviolet light was applied so that the photoresist layer with a width 10 μm larger than the width of the first luminescent layer remained unremoved. Development was carried out with a resist developing solution (manufactured by Tokyo Ohka Kogyo Co., Ltd.; NMD-3) for 20 sec, followed by washing with water to remove the photoresist layer in its exposed areas. Post-baking was carried out at 120° C. for 30 min. Thus, a base body in which the first luminescent layer had been protected by photoresist layers with width 10 μm larger than the width of the first luminescent layer was prepared.

3) Formation of Second Buffer Layer

A coating liquid (Bayer; Baytron P) (0.5 ml) for a buffer layer was dropped on a center part of the substrate for spin coating (while holding at 2500 rpm for 20 sec) to form a buffer layer. The buffer layer had a thickness of 80 nm.

4) Formation of Second Luminescent Layer

A coating liquid (70 parts by weight of polyvinylcarbazole, 30 parts by weight of oxadiazole, 1 part by weight of coumarin 6, and 4900 parts by weight of monochlorobenzene) which is a green luminescent organic material (1 ml) was placed on the buffer layer and was dropped on a center part of the substrate for spin coating (while holding at 2000 rpm for 10 sec) to form a second luminescent layer. The second luminescent layer had a thickness of 80 nm.

A positive-working photoresist liquid (manufactured by Tokyo Ohka Kogyo Co., Ltd.; OFPR-800) (2 ml) was dropped on a center part of the base body for spin coating (while holding at 500 rpm for 10 sec and then holding at 2000 rpm for 20 sec) to form a coating. The coating had a thickness of about 1 μm.

Prebaking was carried out at 80° C. for 30 min. Thereafter, the assembly, together with an exposure mask, was set in an alignment exposure machine, and ultraviolet light was applied to a luminescent layer part to be removed except for the first luminescent layer and the second luminescent layer. Development was carried out with a resist developing solution (manufactured by Tokyo Ohka Kogyo Co., Ltd.; NMD-3) for 20 sec, followed by washing with water to remove the photoresist in its exposed areas.

Post-baking was carried out at 120° C. for 30 min. The buffer layer and the luminescent layer in its parts from which the photoresist layer had been removed was then removed by reactive ion etching using oxygen plasma. The photoresist was removed with acetone. Thereafter, 2 ml of a positive-working photoresist liquid (manufactured by Tokyo Ohka Kogyo Co., Ltd.; OFPR-800) was again dropped on a center part of the base body for spin coating (while holding at 500 rpm for 10 sec and then holding at 2000 rpm for 20 sec) to form a coating. The coating had a thickness of about 1 μm.

Prebaking was carried out at 80° C. for 30 min. Thereafter, the assembly, together with an exposure mask, was set in an alignment exposure machine, and ultraviolet light was applied so that the photoresist layer with a width 10 μm larger than the width of the first luminescent layer and the second luminescent layer remains unremoved. Development was carried out with a resist developing solution (manufactured by Tokyo Ohka Kogyo Co., Ltd.; NMD-3) for 20 sec, followed by washing with water to remove the photoresist in its exposed areas. Post-baking was carried out at 120° C. for 30 min. Thus, a base body protected by photoresist layers with width 10 μm larger than the width of the first luminescent layer and the second luminescent layer was prepared.

5) Formation of Third Buffer Layer

A coating liquid (Bayer; Baytron P) (0.5 ml) for a buffer layer was dropped on a center part of the substrate for spin coating (while holding at 2500 rpm for 20 sec) to form a buffer layer. The buffer layer had a thickness of 80 nm.

6) Formation of Third Luminescent Layer

A coating liquid (70 parts by weight of polyvinylcarbazole, 30 parts by weight of oxadiazole, 1 part by weight of perylene, and 4900 parts by weight of monochlorobenzene) which is a blue luminescent organic material (1 ml) was placed on the buffer layer and was dropped on a center part of the substrate for spin coating (while holding at 2000 rpm for 10 sec) to form a third luminescent layer. The third luminescent layer had a thickness of 80 nm.

A positive-working photoresist liquid (manufactured by Tokyo Ohka Kogyo Co., Ltd.; OFPR-800) (2 ml) was dropped on a center part of the base body for spin coating (while holding at 500 rpm for 10 sec and then holding at 2000 rpm for 20 sec) to form a coating. The coating had a thickness of about 1 μm.

Prebaking was carried out at 80° C. for 30 min. Thereafter, the assembly, together with an exposure mask, was set in an alignment exposure machine, and ultraviolet light was applied to a luminescent layer part to be removed except for the first luminescent layer, the second luminescent layer, and the third luminescent layer. Development was carried out with a resist developing solution (manufactured by Tokyo Ohka Kogyo Co., Ltd.; NMD-3) for 20 sec, followed by washing with water to remove the photoresist in its exposed areas.

Post-baking was carried out at 120° C. for 30 min. The buffer layer and the luminescent layer in its parts from which the photoresist layer had been removed was then removed by reactive ion etching using oxygen plasma. Thus, a base body in which the first luminescent layer, the second luminescent layer, and the third luminescent layer had been protected by the photoresist was prepared. Thereafter, the photoresist was entirely removed with acetone to expose the patterned luminescent layer.

After drying at 100° C. for one hr, on the base body, calcium was vapor deposited in a thickness of 500 angstroms as a second electrode, and silver was vapor deposited in a thickness of 2500 angstroms as a protective layer to prepare a light emitting element.

Evaluation Test of Light Emitting Element

An ITO electrode side of the light emitting element prepared above was connected to a positive electrode, and a silver electrode side was connected to a negative electrode. A direct current was applied with a source meter. Upon the application of 10 V, luminescence was observed from each of the first luminescent layer, the second luminescent layer, and the third luminescent layer, and it was confirmed that the electrode film was formed without any problem.

1. A light emitting element comprising: a substrate; and
a first electrode, a plurality of luminescent layers, and a second electrode provided on said substrate in that order,
said plurality of luminescent layers being provided without providing any partition wall between adjacent luminescent layers.

2. The light emitting element according to claim 1, wherein, when said plurality of luminescent layers are stacked on top of each other, the difference in level between the luminescent layers is not less than 0 μm and not more than 3 μm.

3. The light emitting element according to claim 1, wherein the thickness of each of said plurality of luminescent layers is not less than 0 μm and not more than 3 μm.

4. The light emitting element according to claim 1, which further comprises a buffer layer between said first electrode and said luminescent layer or between said luminescent layer and said second electrode.

5. The light emitting element according to claim 1, which further comprises an insulating layer between said first electrode and said luminescent layer.

6. The light emitting element according to claim 1, wherein said luminescent layer is formed of an organic luminescent material or an inorganic luminescent material.

7. The light emitting element according to claim 1, which is an electroluminescent element.

8. The light emitting element according to claim 1, which is an organic electroluminescent element.

9. A process for producing the light emitting element according to claim 1, said process comprising the step of forming a plurality of luminescent layer patterns by photolithography or printing (except for ink jet printing) without providing any partition wall between adjacent luminescent layers.

10. The process according to claim 9, wherein said printing method is gravure printing, offset printing, screen printing, stamp printing, laser transfer printing, or thermal transfer printing.
